(19) United States
(12) Patent Application Publication
(10) Pub. No.: US 2008/0121922 A1
(43) Pub. Date: May 29, 2008

(54) Light emitting diode package with large viewing angle

(76) Inventor: Hsing Chen, Kukou Township (TW)

Correspondence Address: PRO-TECHTOR INTERNATIONAL SERVICES, 20775 NORADA CT., SARATOGA, CA, 95070, US

(21) Appl. No.: 11/698,706

(22) Filed: Jan. 25, 2007

(30) Foreign Application Priority Data
Nov. 29, 2006 (TW) 095144551

(51) Int. Cl. H01L 33/00; H01L 29/22

(52) U.S. Cl. 257/99; 257/676

(57) ABSTRACT

A light emitting diode package with large viewing angle includes a substrate, a LED chip, transparent housing body, and phosphor matrix. The substrate has an upper surface with a first electrode and a second electrode and a lower surface opposite to the upper surface. The LED chip with a positive electrode and an opposite electrode, the LED chip is mounted on the upper surface of the substrate, and connected from the positive electrode to the first electrode of the substrate by wire, and connected from the negative electrode to the second electrode by wire. The transparent housing body glue is molded on the upper surface of the substrate, and it surrounds the LED chip. And the phosphor matrix is coated on the LED chip, so that the light emitted from the LED chip may turn into white light through the phosphor matrix, and the white light from the LED chip may penetrate the laterals of the transparent housing body. Thus, more lumens are gained and the viewing angle are wider.

### BACKGROUND OF THE INVENTION

1. Field of the Invention

The invention relates a light emitting diode package with large viewing angle, and particular to a package for packaging light emitting diode, the light may be increased by the package.

2. Description of the Related Art

Referring to FIG. 1, it is a conventional white light emitting diode package, includes a substrate 10, a reflection body 12, a LED chip 14, and phosphor matrix 16. The substrate 10 has an upper surface 18 and a lower surface 20, the upper surface 18 of the substrate 10 is formed with a chip region 22, and the side of the chip region 22 is formed with a first electrode 181 and a second electrode 182. The reflection body 12 is form of white plastics, is molded on the upper surface 18 of the substrate 10 to form a cavity 24 together with the substrate 10. The LED chip 14 is mounted on the chip region 22 of the substrate 10, and is located within the cavity 24, and is connected from the first electrode 181 and second electrode 182 by wires 26. The phosphor matrix 16 is coated on the cavity 24 to cover the LED chip 14.

The reflection body 12 is form of the white plastics of the conventional light emitting diode, which may reflected light only in upward direction of the LED chip 14. But can not allow the light penetrate through reflection body 12 walls.

But the amount of the phosphor 16 is difficult to control in manufacturing processes, too thick of the phosphor matrix layer 16 will decrease the light emitted, but too thin of the layer is not acceptable to cover the bonding wire.

### SUMMARY OF THE INVENTION

An objective of the invention is to provide a light emitting diode package with large viewing angle, and capable of increasing the light of the LED chip.

To achieve the above-mentioned objective, the invention includes a substrate, a LED chip, transparent housing body, and phosphor matrix. The substrate has an upper surface and lower surface, there are first electrode and second electrode mounted on the upper surface. The LED chip is mounted on the upper surface of the substrate, and is connected from the positive electrode to the first electrode of the substrate by wire, and is connected from negative electrode to the second electrode by wire. The transparent housing body is molded on the upper surface of the substrate, and it surrounds the LED chip; and phosphor matrix is coated on the LED chip, so that the light emitting from the LED chip may turn into white light through the phosphor matrix, and the white light may be emitting via lateral and top directions transparent housing body

The invention raises the luminosity up to 30%-35%. Comparing to the conventional package

### BRIEF DESCRIPTION OF THE DRAWINGS

FIG. 1 is a schematic illustration showing a conventional light emitting diode package.

FIG. 2 is a cross-sectional schematic illustration showing a light emitting diode package with large viewing angle of this present invention.

FIG. 3 is schematic illustration showing another device of this present invention.

FIG. 4 is showing a light intensity angular distribution of conventional light emitting diode package.

FIG. 5 is showing a light intensity angular distribution of this invention of light emitting diode package with large viewing angle.

### DETAILED DESCRIPTION OF THE INVENTION

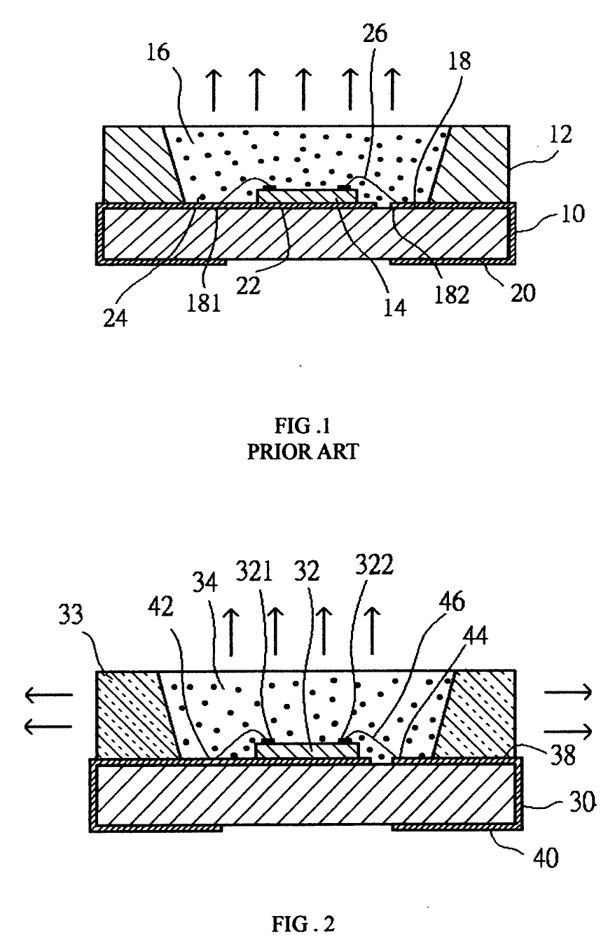

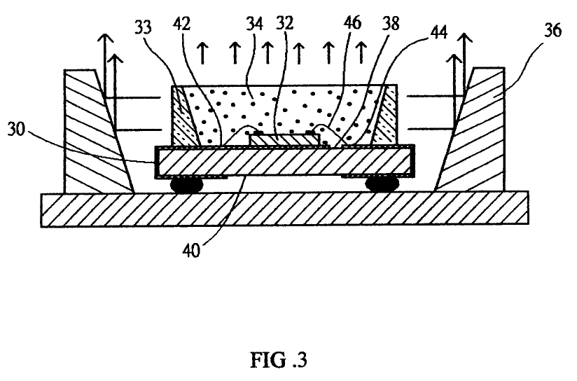

Please refer to FIG. 2 and FIG. 3, a light emitting diode package with large viewing angle includes a substrate 30, a LED chip 32, transparent housing body 33, phosphor matrix 34, and a outer reflector 36.

The substrate 30 has an upper surface 38 with a first electrode 42 and a second electrode 44, and a lower surface 40 opposite to the upper surface 38.

The LED chip 32 with a positive electrode 321 and a negative electrode 322, the LED chip 32 is mounted on the upper surface 38 of the substrate 30, and is connected from the positive electrode 321 to the first electrode 42 of the substrate 30 by wire 46, and is connected from the negative electrode 322 to the second electrode 44 of the substrate 30 by wire 46.

The transparent housing body 33 is molded on the upper surface 38 of the substrate 30, and it surrounds the LED chip 32.

The phosphor matrix 34 is coated on the LED chip 32, so that the light emitted from the LED chip 32 may turn into produce white through the phosphor matrix 34, and the white light from the LED chip 32 may emit via the lateral and top directions through the transparent housing body 33.

According to inventor's test result shown, the light of this invention may increase above 30-35 percent, and the viewing angle may be widen to 150%.

Please refer to FIG. 3, this invention further comprises an outer reflector body 36, which encapsulates the FIG. 2 device and reflects the lateral light from the LED chip 32, thus, it may enhance the light from LED chip.

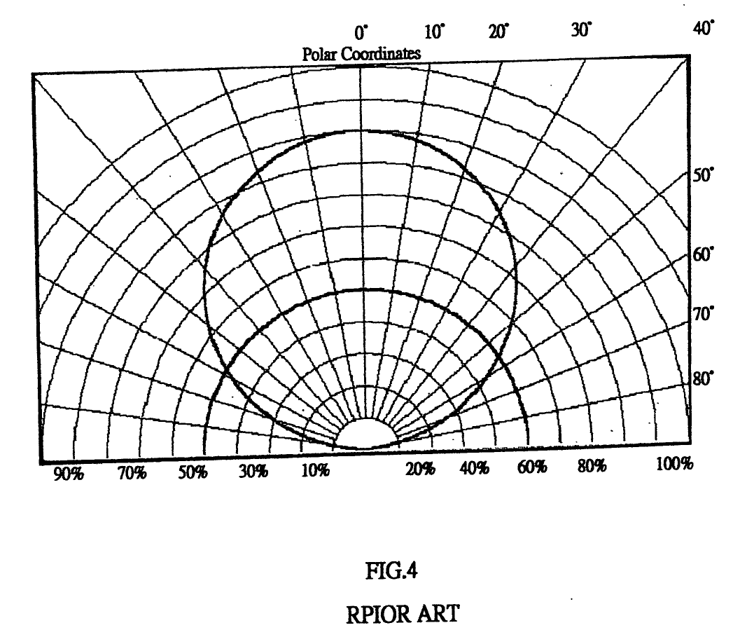

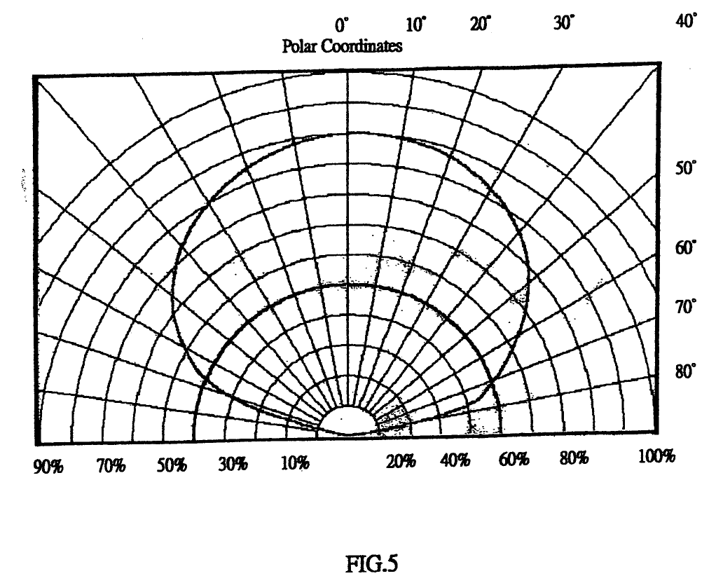

Please refer to FIG. 4, and FIG. 5, inventor's test result shown, the light of this invention may be increased about 30 percent more than the conventional one.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. A light emitting diode package with large viewing angle, the package comprising:
a substrate having an upper surface with a first electrode and an second electrode and a lower surface opposite to the upper surface;
a LED chip with a positive electrode and an negative, the LED chip mounted on the upper surface of the substrate, and connected from the positive electrode to the first electrode of the substrate by wire, and connected from the negative electrode to the second electrode by wire;
a transparent housing body molded on the upper surface of the substrate, and surrounds the LED chip; and
a phosphor matrix coated on the LED chip, so that the light emitted from the LED chip may turn into white light through the phosphor matrix, and the white light from the LED chip may penetrate the laterals of the transparent housing body.

2. The light emitting diode with large viewing angle according to claim 1, wherein package includes a outer reflector, which encapsulates the transparent housing body to reflects the light from LED chip.
